(19) United States
(12) Patent Application Publication
(10) Pub. No.: US 2007/0222646 A1
(43) Pub. Date: Sep. 27, 2007

(54) Input method of electronic devices with a compact keypad

(75) Inventors: Ronald Lee, Sindian City (TW); Gino Li, Sindian City (TW)

Correspondence Address: BACON & THOMAS, PLLC, 625 SLATERS LANE, FOURTH FLOOR, ALEXANDRIA, VA, 22314, US

(73) Assignees: Ronald LEE, Sindian City (TW); Gino LI, Sindian City (TW)

(21) Appl. No.: 11/709,227

(22) Filed: Feb. 22, 2007

(30) Foreign Application Priority Data
Mar. 8, 2006 (TW) 095107781

(51) Int. Cl. H03M 11/00

(52) U.S. Cl. 341/22

(57) ABSTRACT

The present invention provides an input method for electronic device with a compact keypad, which comprises plurality of number keys, to which multiple letter groups are assigned respectively. The method for inputting letters comprises the following steps: pressing the number key that corresponds to the letter wished to be inputted; and then pressing the number key that corresponds to the numerical order of that inputted letter within the sequence of that letter group. Using this easy input method in any electronic device equipped with a compact keypad allows the user to quickly yet accurately input any alphanumerical data without the use of any on-screen display menus.

### BACKGROUND OF THE INVENTION

1. Field of the Invention

The present invention relates to an input method and, more particularly, to an input method for electronic devices with a compact keypad.

2. Description of Related Art

With the development in the wireless communication and the Internet industries, the input method, which was originally designed for computer data entry, has now been further employed on modern electronic devices, for instances, cellular phones, stock messenger devices, PDAs and etc. However, due to their relatively small size, these electronic devices usually come with a compact keypad that comprises only the number keys along with few functional keys, such that to directly apply the input method that is used with a computer keyboard to the aforementioned electronic devices would be inappropriate.

The input method for the small electronic devices that are commonly seen nowadays are mostly letter based; however, due to limited keys, the input speed has to decrease, as even some letters would take up to four keystrokes in order to obtain the correct input.

To reduce the number of keystrokes, conventionally the letters are inputted by selecting from a group of candidate letters shown on the displayed menus on the screen of an electronic device once it is determined whether there is a space followed by the inputted letter. However, since the method requires a screen in order to proceed, it cannot be applied to every electronic device, for example, a telephone for household use or a remote control to a television set.

### SUMMARY OF THE INVENTION

Having considered the troubles that one may have encountered when using the conventional method for inputting letters in an electronic device, the present invention provides an electronic device having a compact keypad, which comprises a plurality of number keys, to which multiple letter groups are assigned respectively, each letter group comprising a plurality of letters arranged in a predefined sequence, and the method thereof for inputting letters comprising: pressing a number key that is assigned with the letter wished to be inputted; and pressing a number key on the keypad that has a value equal to an order of that inputted letter within the sequence of that letter group. With such easy input method along with the electronic device having a compact keypad, it allows the user to quickly yet accurately input data without the use of any on-screen display menus.

Aforementioned multiple letter groups are arranged in alphabetical order that are divided into eight groups, such as ‘ABC’, ‘DEF’, ‘GHI’, ‘JKL’, ‘MNO’, ‘PQRS’, ‘TUV’ and ‘WXYZ’, and are assigned respectively to the number keys 2˜9.

Further, the present invention offers numeral inputs, by which the method comprises: pressing the number key ‘0’ or the number key ‘1’ followed by a number key in order to input the number corresponding to the number key.

Moreover, the electronic device mentioned in the present invention can be any electronic communication device, e.g. a telephone, a cellular phone, a facsimile machine, PDA and etc. The keypad of these electronic communication devices further comprise a first special character key. By pressing the first special character key then a number key, the corresponding number on the number key can be inputted. The first special character key is a star key ‘*’ or a pound key ‘#’.

According to the input method of the present invention, the keypad further comprises a second special character key, with which the method further includes: pressing the second special character key once on the keypad to enter a space, whereas pressing the second special character key for two successive times for deleting all that had been previously inputted. The second special character key is a pound key ‘#’ or a star key ‘*’.

The electronic device mentioned in the present invention also can be any electronic control unit, e.g. a remote control to a television set or a remote control to a multimedia player. These electronic control units further comprise two functional keys, with which the method further includes: pressing the two function keys on the keypad once simultaneously to enter a space; pressing the two function keys on the keypad twice simultaneously to delete all that had been previously inputted. The two function keys can be any two of the followings: a volume up key, a volume down key, a channel up key and a channel down key.

Not only does the present invention offers alphanumerical inputs, it also achieves the above objectives by allowing users to key in data in more varieties of electronic devices that are equipped with a compact keypad.

### BRIEF DESCRIPTION OF THE DRAWINGS

FIG. 1 is a diagram showing a keypad in the present invention.

FIG. 2 is a perspective view of the telephone for household use according a preferred embodiment of the present invention.

FIG. 3 is a top plan view of a remote control to a television set according to another embodiment of the present invention.

### DETAILED DESCRIPTION OF THE PREFERRED EMBODIMENT

The following is to describe the present invention with specific preferred embodiments such that the disclosure will be thorough and complete and fully convey the concept and the merits of the invention to those skilled in the art. The present invention may, however, be embodied in many other possible modifications and variations without departing from the scope of the invention herein.

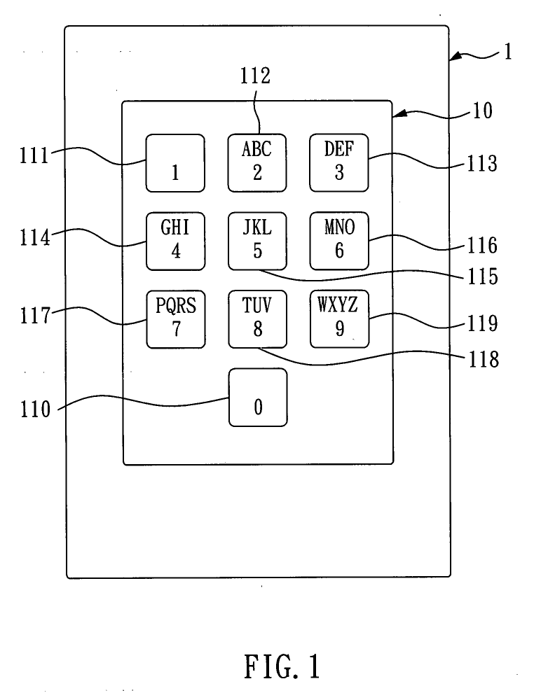

As shown in FIG. 1, an electronic device having a compact keypad 1, which is referred in the present invention, has a keypad 10 comprising a plurality of number keys 110-119, to which multiple letter groups are assigned. Each letter group includes a plurality of letters arranged in a predefined sequence. These multiple letter groups are arranged in alphabetical order and assigned respectively to the number keys 110˜119. These eight letter groups, ‘ABC’, ‘DEF’, ‘GHI’, ‘JKL’, ‘MNO’, ‘PQRS’, ‘TUV’ and ‘WXYZ’, are assigned respectively to the number key ‘2’ 112, the number key ‘3’ 113, the number key ‘4’ 114, the number key ‘5’ 115, the number key ‘6’ 116, the number key ‘7’ 117, the number key ‘8’ 118 and the number ‘9’ 119 of the keypad 10. The layout for arranging above letter groups on the number keys 110˜119 follows which that has been commonly used on a standard keypad of, for example, a telephone for household use.

Based on the aforementioned keypad, in a case where the user wishes to input a letter, the user first presses a number key, from the number keys 110-119, that is assigned with the letter group containing the letter wished to be inputted, and next the user presses a number key, from the number keys 110˜119, which has a value corresponds to the order of that letter within the sequence of that letter group. For example, when a letter ‘K’ is to be inputted, first the number key ‘5’ 115, which contains the letter ‘K’, is pressed. Then, since the letter ‘K’ is arranged on the second order within the sequence of the letter group ‘JKL’, the user then presses the number key ‘2’ 112, which has a value of 2 equal to the above order, on the keypad 10, such that the input of letter ‘K’ is complete. Accordingly all letters and their required inputs are listed in Table 1 as follows:

TABLE 1

| Letter to be inputted | Required inputs |
|---|---|
| A | “2” and “1” |
| B | “2” and “2” |
| C | “2” and “3” |
| D | “3” and “1” |
| E | “3” and “2” |
| F | “3” and “3” |
| G | “4” and “1” |
| H | “4” and “2” |
| I | “4” and “3” |
| J | “5” and “1” |
| K | “5” and “2” |
| L | “5” and “3” |
| M | “6” and “1” |
| N | “6” and “2” |
| O | “6” and “3” |
| P | “7” and “1” |
| Q | “7” and “2” |
| R | “7” and “3” |
| S | “7” and “4” |
| T | “8” and “1” |
| U | “8” and “2” |
| V | “8” and “3” |
| W | “9” and “1” |
| X | “9” and “2” |
| Y | “9” and “3” |
| Z | “9” and “4” |

Since the letters on the number keys 110-119 are arranged in alphabetical order, the users are able to input letters easily by first locating the letters on the number keys 110-119 and then pressing the number keys spontaneously that correspond to the respective numerical orders of the letters. The method hardly requires any learning or memorization by the users, and each letter takes merely two keystrokes to complete the input, which helps achieve a result of fast and efficient data entry. Also, since the letter groups on the number keys 110-119 are arranged as same as the standard layout on regular telephones, without any additional learning, most users, who have already been familiar with such layout, can effortlessly locate the letters that they are looking for and correctly input them.

In case where a number is to be inputted, the number key ‘0’ 110 on the keypad 10 is first pressed and followed by a number key from the number keys 110-119, such that the corresponding number on that number key will be inputted. For example, when a number ‘6’ is to be inputted, first the number key ‘0’ 110 is pressed, followed by the number key ‘6’ 116, and the number ‘6’ will be inputted. Accordingly all numbers and their required inputs are listed in Table 2 as follows:

TABLE 2

| Number to be inputted | Required inputs |
|---|---|
| 0 | “0” and “0” |
| 1 | “0” and “1” |
| 2 | “0” and “2” |
| 3 | “0” and “3” |
| 4 | “0” and “4” |
| 5 | “0” and “5” |
| 6 | “0” and “6” |
| 7 | “0” and “7” |
| 8 | “0” and “8” |
| 9 | “0” and “9” |

Since the numeral input begins with ‘0’ and that the number key ‘0’ 110 would not be used in any way when inputting a letter, there shall not be any conflict or confusion in inputting a letter and a number.

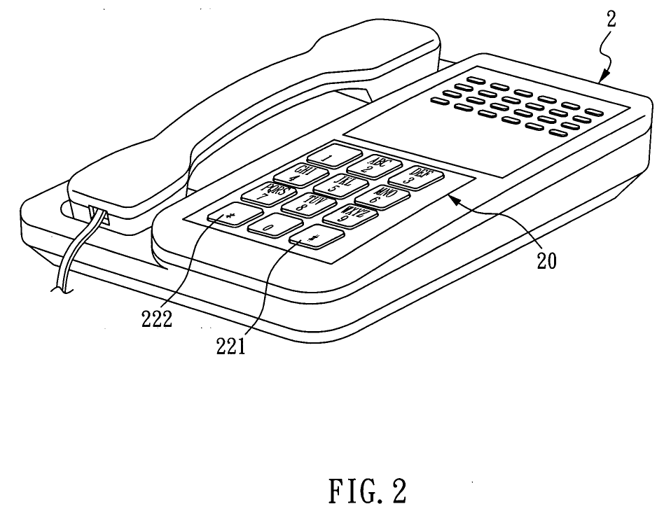

Further, in a case where the users wish to enter a space or delete those that have been previously inputted, some keys other than the number keys can be utilized for such purpose. FIG. 2 shows a common electronic communication device, a telephone 2 for household use. The keypad 20 of the telephone 2, other than having number keys for using the aforementioned methods to input letters and numbers, further comprises a pound key ‘#’ 221 and a star key ‘*’ 222. The keypad 20 can be set up such that when the pound key ‘#’ 221 is pressed once, a space will be entered; when the pound key ‘#’ 221 is pressed twice, then everything that has been previously inputted will be deleted accordingly. The keypad 20, of course, can also be set up such that when the star key ‘*’ 222 is pressed once, a space will be entered; when the star key ‘*’ 222 is pressed twice, then everything that has been previously inputted will be deleted accordingly. By repeating the above steps, the users are able to complete inputting alphanumerical data according to their needs.

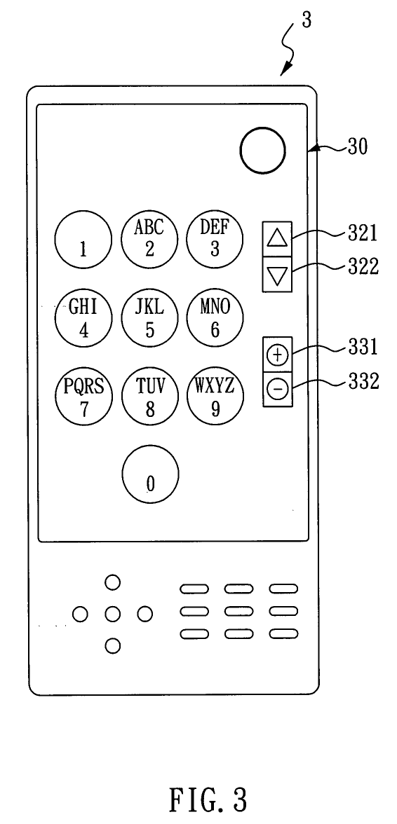

FIG. 3 illustrates another preferred embodiment of the present invention, where a remote control 3 to a television set is used to input alphanumerical data. The keypad 30 of the remote control 3 comprises number keys that provide alphanumerical inputs using the abovementioned methods. The keypad 30 of the remote control 3 further comprises a channel up key ‘Δ’ 321, a channel down key ‘∇’ 322, a volume up key ‘⊕’ 331 and a volume down key ‘⊖’ 332. The key pad 30 can be set up such that when both the channel up key ‘Δ’ 321 and the volume up key ‘⊕’ 331 are pressed simultaneously for one time, a space can be entered; when the channel up key ‘Δ’ 321 and the volume up key ‘⊕’ 331 are pressed simultaneously for two successive times, all that have been previously inputted will be deleted. The key pad 30, of course, can also be set up in such way that when the channel down key ‘∇’ 322 and the volume down key ‘⊖’ 332 are pressed once simultaneously, a space can be entered; whereas when the channel down key ‘∇’ 322 and the volume down key ‘⊖’ 332 are pressed simultaneously for two successive times, all that have been previously inputted will be deleted. By repeating the above steps, the users are able to complete inputting alphanumerical data according to their needs.

Although the present invention has been explained in relation to its preferred embodiment, it is to be understood that many other possible modifications and variations can be made without departing from the scope of the invention as hereinafter claimed.

What is claimed is:

1. An input method for electronic device with a compact keypad, comprising a plurality of number keys, to which multiple letter groups are assigned respectively, each letter group comprising a plurality of letters arranged in a predefined sequence, said method comprising the following steps:
pressing a number key that is assigned with the letter wished to be inputted; and
pressing a number key that has a value equal to an order of that inputted letter within the sequence of said letter group.

2. The method as claimed in claim 1, wherein said multiple letter groups are allocated on said number keys in alphabetical order.

3. The method in claim 2, wherein eight letter groups, consisting of ‘ABC’, ‘DEF’, ‘GHI’, ‘JKL’, ‘MNO’, ‘PQRS’, ‘TUV’ and ‘WXYZ’, are allocated on the number keys 2˜9 on said keypad respectively.

4. The method as claimed in claim 2, wherein the method further comprises the following step:
pressing the number key ‘0’ then a number key on said keypad to input the number corresponding to said number key.

5. The method as claimed in claim 1, wherein said keypad further comprises a first special character key, with which said method further includes the following step:
pressing said first special character key then a number key on said keypad to input the number corresponding to said number key.

6. The method as claimed in claim 5, wherein said first special character key is a start key ‘*’.

7. The method as claimed in claim 2, wherein said keypad further comprises a second special character key, with which said method further includes the following step:
pressing said second special character key on said keypad to enter a space.

8. The method for inputting letters in claim 7, wherein the method further includes the following step:
pressing said second special character key for two successive times to delete all that had been previously inputted.

9. The method for inputting letters in claim 7, wherein said second special character key is a pound key ‘#’.

10. The method for inputting letters in claim 2, wherein said keypad further comprises two function keys, with which said method further includes the following step:
pressing said two function keys on said keypad once simultaneously to enter a space.

11. The method as claimed in claim 10, wherein said method further includes:
pressing said two function keys on said keypad twice simultaneously to delete all that had been previously inputted.

12. The method as claimed in claim 11, wherein said two function keys are a volume up key ‘⊕’ and a channel up key ‘Δ’.
